(19) United States
(12) Patent Application Publication
(10) Pub. No.: US 2021/0395880 A1
(43) Pub. Date: Dec. 23, 2021

(54) DEPOSITION APPARATUS

(71) Applicant: ULVAC, INC., Chigasaki-shi, Kanagawa (JP)

(72) Inventors: Yuko KATO, Chigasaki-shi, Kanagawa (JP); Takahiro YAJIMA, Chigasaki-shi, Kanagawa (JP); Fumio NAKAMURA, Chigasaki-shi, Kanagawa (JP); Yoshinobu UE, Chigasaki-shi, Kanagawa (JP); Shogo OGURA, Chigasaki-shi, Kanagawa (JP)

(21) Appl. No.: 17/287,774

(22) PCT Filed: Dec. 20, 2019
(86) PCT No.: PCT/JP2019/050210

§ 371 Date: Apr. 22, 2021

(30) Foreign Application Priority Data
Feb. 25, 2019 (JP) 2019-031832

(51) Int. Cl. C23C 14/58; C23C 14/12; C23C 14/24

(52) U.S. Cl. CPC C23C 14/58; C23C 14/24; C23C 14/12

(57) ABSTRACT

The deposition apparatus includes a chamber including a deposition space, a stage that supports a substrate, a light source, a gas supply, and a heater. The light source includes an emission source that emits an energy ray and is disposed to face the deposition space. The gas supply includes a shower plate and a gas diffusion space. The shower plate includes a first surface that faces the light source, a second surface that faces the stage, and a plurality of through-holes that penetrates the first surface and the second surface, the shower plate allowing the energy ray to transmit therethrough. The gas diffusion space faces the first surface and diffuses raw material gas including an energy ray-curable resin that cures when the energy ray-curable resin is irradiated with the energy ray. The gas supply supplies the raw material gas into the deposition space from the gas diffusion space. The heater heats the first surface of the shower plate.

### TECHNICAL FIELD

The present invention relates to a deposition apparatus that forms a resin layer constituted of an energy ray-curable resin.

### BACKGROUND ART

For forming a resin layer on a substrate by curing an energy ray-curable resin such as an ultraviolet curable resin, the following two steps are typically performed. Specifically, the steps are a step of making a cooling stage support the substrate and supplying raw material gas including the resin onto the substrate supported by the cooling stage and a step of emitting light such as an ultraviolet ray onto the substrate to form the resin layer cured on the substrate.

In particular, in recent years, a deposition apparatus that performs the step of supplying the raw material gas onto the substrate and the step of forming the resin layer cured on the substrate with the ultraviolet ray inside a single vacuum chamber rather than individually performing those steps in separate vacuum chambers has been provided. For example, Patent Literature 1 has disclosed a deposition apparatus including a gas supply with a piping for discharging raw material gas.

### CITATION LIST

### Patent Literature

Patent Literature 1: Japanese Patent Application Laid-open No. 2013-064187

### DISCLOSURE OF INVENTION

### Technical Problem

However, in the deposition apparatus disclosed by Patent Literature 1, when the raw material gas is discharged from the piping, a distribution of the film thickness of the resin layer formed on the substrate may not be uniform and it may be impossible to obtain desired deposition quality. In addition, the productivity may be lowered because of deposit of resin in the gas supply, for example, in the piping.

In view of the above-mentioned circumstances, it is an object of the present invention to provide a deposition apparatus by which the deposition quality and the productivity can be improved.

### Solution to Problem

In order to accomplish the above-mentioned object, a deposition apparatus according to an embodiment of the present invention includes a chamber, a stage, a light source, a gas supply, and a heater.

The chamber includes a deposition space.

The stage is disposed in the deposition space and supports a substrate.

The light source includes an emission source that emits an energy ray and is disposed to face the deposition space.

The gas supply includes a shower plate and a gas diffusion space.

The shower plate includes a first surface that faces the light source, a second surface that faces the stage, and a plurality of through-holes that penetrates the first surface and the second surface, the shower plate allowing the energy ray to transmit therethrough.

The gas diffusion space faces the first surface and diffuses raw material gas including an energy ray-curable resin that cures when the energy ray-curable resin is irradiated with the energy ray.

The gas supply supplies the raw material gas into the deposition space from the gas diffusion space.

The heater heats the first surface of the shower plate.

With this configuration, since the gas supply includes the shower plate and the gas diffusion space, the raw material gas the pressure of which has been increased by the gas diffusion space is supplied into the deposition space from the plurality of through-holes of the shower plate. Accordingly, the flow rate of the raw material gas supplied into the deposition space can be made uniform and the distribution of the film thickness can be made uniform. Therefore, the deposition quality can be improved. In addition, the first surface on the side of the gas diffusion space of the shower plate is heated by the heater. Accordingly, the energy ray-curable resin can be prevented from sticking to inner walls of the gas diffusion space and the through-holes, lowering of the transmittance to an energy ray and clogging in the through-hole can be suppressed, and the productivity can be improved.

The heater may include a transparent conductive film formed on the first surface of the shower plate.

Accordingly, the first surface is heated by resistance heating of the transparent conductive film. Therefore, transmittance of the shower plate to the energy ray can be ensured and the maintenance of the heater can be made easy.

For example, the transparent conductive film may include indium oxide tin (ITO).

Accordingly, the transparent conductive film can have sufficient transmittance to an energy ray.

Moreover, the transparent conductive film may have a plurality of holes that communicates with the plurality of through-holes

Accordingly, the raw material gas can be supplied even in a case where a large area of the first surface is covered with the transparent conductive film.

For example, the shower plate may be constituted of quartz glass.

Accordingly, transmittance of the shower plate to an energy ray can be sufficiently ensured.

As a specific configuration, the chamber may further include
an aperture that makes the deposition space opened to the light source, and
a top plate that closes the aperture and allows the energy ray to transmit therethrough, and

the gas diffusion space may be configured as a space sandwiched between the top plate and the shower plate.

Accordingly, it is possible to form the gas diffusion space by utilizing the top plate of the chamber and the number of components can be thus reduced. Therefore, a configuration easy for maintenance can be provided.

### Advantageous Effects of Invention

As described above, in accordance with the present invention, the deposition quality and the productivity can be improved.

### BRIEF DESCRIPTION OF DRAWINGS

FIG. 1 A schematic cross-sectional view showing a deposition apparatus according to an embodiment of the present invention.

FIG. 2 A schematic cross-sectional view showing a shower plate and a transparent conductive film shown in FIG. 1 in an enlarged state.

FIG. 3 A schematic plan view showing the transparent conductive film.

FIG. 4 A schematic cross-sectional view showing a deposition apparatus according to a comparative example of this embodiment.

FIG. 5 A main-part cross-sectional view of a deposition apparatus according to another embodiment of the present invention.

FIG. 6 A main-part plan view of a deposition apparatus according to still another embodiment of the present invention.

FIG. 7 A main-part plan view of a deposition apparatus according to still another embodiment of the present invention.

FIG. 8 A main-part cross-sectional view of a deposition apparatus according to still another embodiment of the present invention.

### MODE(S) FOR CARRYING OUT THE INVENTION

Hereinafter, an embodiment of the present invention will be described with reference to the drawings.

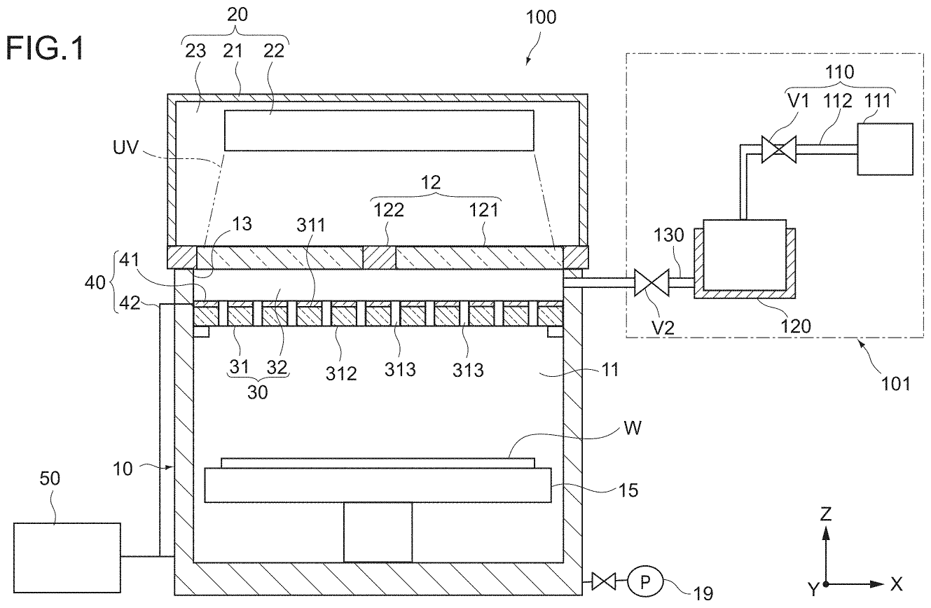

FIG. 1 is a schematic cross-sectional view showing a deposition apparatus 100 according to an embodiment of the present invention. In the figure, the X-axis direction and the Y-axis direction denote horizontal directions orthogonal to each other and the Z-axis direction denotes a direction orthogonal to the X-axis direction and the Y-axis direction.

[Deposition Apparatus]

The deposition apparatus 100 is configured as a deposition apparatus for forming on a substrate W a layer constituted of an ultraviolet curable resin that is an energy ray-curable resin. The deposition apparatus 100 is an apparatus for forming an ultraviolet curable resin layer by emitting an ultraviolet ray onto the substrate W after supplying raw material gas including the ultraviolet curable resin onto the substrate W.

The deposition apparatus 100 includes a chamber 10, a stage 15, a light source 20, a gas supply 30, and a heater 40.

(Chamber)

The chamber 10 includes a deposition space 11, an aperture 13 formed in an upper portion of the deposition space 11, and a top plate 12 that hermetically closes the aperture 13.

The chamber 10 is a metal vacuum container having an opened upper portion and includes the deposition space 11 in the inside. The deposition space 11 is configured to be capable of being evacuated or maintained in a predetermined reduced-pressure atmosphere via a vacuum pumping system 19 connected to a bottom portion of the chamber 10.

The top plate 12 allows an ultraviolet ray UV transmit therethrough. For example, the top plate 12 includes window portions 121 that allow ultraviolet rays UV to transmit therethrough and a frame portion 122 that supports the window portions 121. The window portions 121 is constituted of an ultraviolet transmissive material such as quartz glass and the frame portion 122 is constituted of a metal material such as an aluminum alloy. The number of window portions 121 is not particularly limited and may be two or more or may be one.

(Stage)

The stage 15 is disposed in the deposition space 11 and configured to be capable of supporting the substrate W. The stage 15 is cooled by a cooling medium such as cooling water, for example. It should be noted that a configuration in which the substrate W cooled at the predetermined temperature or less is fed into the deposition space 11 may be employed.

Although the substrate W is the glass substrate here, the substrate W may be a semiconductor substrate. The shape and size of the substrate are not particularly limited and the substrate may be rectangular or circular. Devices may be formed in advance on a deposition surface of the substrate W. In this case, a resin layer deposited on the substrate W functions as a protection film for the devices.

(Light Source)

The light source 20 includes a cover 21 and an emission source 22. The cover 21 is disposed on the top plate 12 and includes a light source space 23 in which the emission source 22 is accommodated. The light source space 23 is in the atmosphere, for example. The emission source 22 is a light source that emits an ultraviolet ray UV that is the energy ray toward the stage 15 via the window portions 121 of the top plate 12 and is typically constituted of an ultraviolet lamp, though not limited thereto. A light source module in which a plurality of light emitting diodes (LEDs) emits ultraviolet rays UV is arranged in a matrix form may be employed as the emission source 22.

(Gas Supply)

The gas supply 30 supplies the deposition space 11 with raw material gas including a resin (ultraviolet curable resin) that cures when the resin (ultraviolet curable resin) is irradiated with an ultraviolet ray UV. The gas supply 30 includes a shower plate 31 and a gas diffusion space 32.

The shower plate 31 has a plate shape and is constituted of an ultraviolet transmissive material such as quartz glass. The shower plate 31 is fixed to an inner wall surface of the chamber 10 via an appropriate fixation member.

The shower plate 31 includes a first surface 311 that faces the light source 20, a second surface 312 that faces the stage 15, and a plurality of through-holes 313 that penetrates the first surface 311 and the second surface 312.

The plurality of through-holes 313 penetrates the shower plate 31 in the thickness direction such that the gas diffusion space 32 and the deposition space 11 communicate with each other. The through-holes 313 are configured to be capable of supplying the raw material gas into the deposition space 11 from the gas diffusion space 32. The plurality of through-holes 313 may be formed at constant intervals in the surface or may be formed at different intervals. Moreover, the through-holes 313 may have the same diameter or may have different diameters.

The gas diffusion space 32 diffuses the raw material gas. For example, the gas diffusion space 32 is configured as a space sandwiched between the top plate 12 and the shower plate 31 and is defined by the top plate 12, the shower plate 31, and side walls of the chamber 10. The above-mentioned raw material gas is introduced into the gas diffusion space 32 via a raw material gas generator 101.

An acrylic resin, for example, can be used as the ultraviolet curable resin material. Moreover, a polymerization initiator and the like may be added to such a resin for the use. The raw material gas generator 101 installed outside the chamber 10 generates the raw material gas including that resin. The raw material gas generator 101 introduces the raw material gas including the resin into the gas diffusion space 32 of the gas supply 30 via a piping 130.

The raw material gas generator 101 includes a resin material-feeding line 110, a vaporizer 120, and the piping 130.

The resin material-feeding line 110 includes a tank 111 reserving a liquid resin material and a piping 112 for transporting the resin material into the vaporizer 120 from the tank 111. Carrier gas constituted of inert gas such as nitrogen, for example, is used for transporting the resin material into the vaporizer 120 from the tank 111. Moreover, a valve V1 or a liquid flow rate controller or the like (not shown) may be attached to the piping 112.

The raw material gas generated by the vaporizer 120 is supplied into the gas diffusion space 32 of the gas supply 30 via the piping 130. A valve V2 is attached to the piping 130 such that the gas flow into the gas diffusion space 32 can be adjusted. In addition, the flow rate of the gas flowing into the gas diffusion space 32 can also be controlled in a case where the flow rate controller (not shown) is attached.

Here, when the raw material gas introduced into the gas diffusion space 32 is cooled below the evaporating temperature, the resin material contained in the raw material gas can be deposited on the inner walls of the gas diffusion space 32 and the inside of the through-holes 313. For preventing it, the deposition apparatus 100 further includes the heater 40 that heats the first surface 311 of the shower plate 31.

(Heater)

In this embodiment, the heater 40 includes a transparent conductive film 41 formed on the first surface 311 of the shower plate 31 and a wiring 42 connected to the transparent conductive film 41. The heater 40 is configured to be capable of heating the gas diffusion space 32 and the shower plate 31 at an appropriate temperature that is equal to or higher than the evaporating temperature of the above-mentioned resin material by resistance heating of the transparent conductive film 41. The wiring 42 may be connected to a control unit 50 of the deposition apparatus 100, which will be described later, as shown in FIG. 1, for example, or may be connected to another power supply device.

The transparent conductive film 41 includes indium oxide tin (ITO), for example. Accordingly, it is possible to heat the gas diffusion space 32 and the shower plate 31 while sufficiently ensuring transmittance to an energy ray for the stage 15.

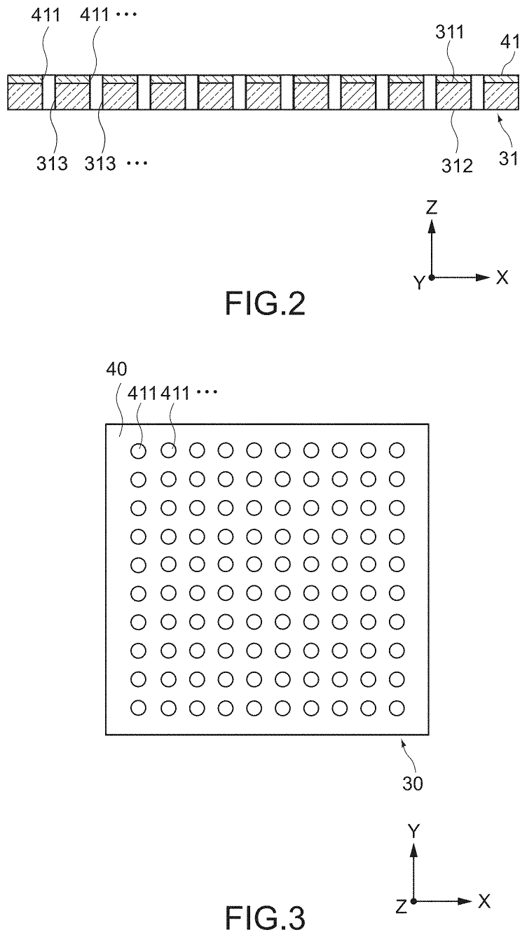

FIG. 2 is a schematic cross-sectional view showing the shower plate 31 and the transparent conductive film 41 formed thereon in an enlarged state. FIG. 3 is a schematic plan view showing the transparent conductive film 41 formed on the shower plate 31.

In this embodiment, the transparent conductive film 41 is configured to cover the entire first surface 311 of the shower plate 31. Also with this configuration, the transparent conductive film 41 includes a plurality of holes 411 that communicates with the plurality of through-holes 313 in order to secure the supply of the raw material gas. The plurality of holes 411 is provided corresponding to the through-holes 313, respectively, and has substantially the same diameter as each corresponding through-hole 313.

The deposition apparatus 100 further includes the control unit 50. The control unit 50 is typically constituted of a computer and controls the respective parts of the deposition apparatus 100.

[Deposition Method]

Subsequently, a deposition method using the deposition apparatus 100 according to this embodiment, which is configured as described above, will be described.

(Deposition Step)

The deposition step includes a step of supplying a raw material gas including an ultraviolet curable resin and a step of curing a resin layer with an ultraviolet ray.

In the deposition step, the pressure of the deposition space 11 is adjusted at a predetermined degree of vacuum by the vacuum pumping system 19 and the substrate W is disposed on the stage 15 cooled at a predetermined temperature or less. The heater 40 heats the gas supply 30 at a temperature that is equal to or higher than the evaporating temperature of the ultraviolet curable resin.

In the step of supplying the raw material gas, the raw material gas including the ultraviolet curable resin generated by the raw material gas generator 101 is introduced into the gas supply 30 via the piping 130. The raw material gas introduced into the gas supply 30 is diffused in the gas diffusion space 32 and is supplied onto the entire surface of the substrate W on the stage 15 via the plurality of through-holes 313 of the shower plate 31. The ultraviolet curable resin in the raw material gas supplied onto the surface of the substrate W is condensed and deposited on the surface of the substrate W cooled at a temperature that is equal to or lower than the condensation temperature.

In the step of curing the ultraviolet curable resin, the supply of the raw material gas is suspended and the ultraviolet ray UV is emitted to the stage 15 of the stage 15 from the emission source 22 of the light source 20. Since the gas supply 30 is constituted of the material that allows the ultraviolet ray to transmit therethrough, a sufficient amount of ultraviolet light UV is emitted to the substrate W on the stage 15 via the gas supply 30. Accordingly, a cured layer of the ultraviolet curable resin is formed on the substrate W.

After the curing step is completed, the substrate W is discharged from the deposition space 11 and a substrate W not subjected to deposition is newly fed into the deposition space. Then, each of the above-mentioned steps is similarly performed. Accordingly, the single deposition apparatus can form an ultraviolet curable resin layer having a predetermined thickness on the substrate W.

[Actions and Effects of This Embodiment]

In this embodiment, the raw material gas is supplied into the gas diffusion space 32 and the entire inside of the gas diffusion space 32 is maintained at a certain pressure or more by the raw material gas. If the gas supply does not include the shower plate and is constituted of a plurality of gas discharge pipings or the like, a difference in flow rate and pressure of the raw material gas is caused between a portion closer to the raw material gas generator 101 and an end portion further from the raw material gas generator 101. Therefore, a difference is caused in flow rate of the raw material gas discharged from the gas discharge pipings and it is difficult to make the distribution of the film thickness of the ultraviolet curable resin layer in the surface uniform.

On the other hand, in this embodiment, the pressure of the raw material gas inside the gas diffusion space 32 can be made more uniform. Accordingly, the flow rate of the raw material gas in the through-holes 313 at the center of the shower plate 31 and the through-holes 313 at the periphery can be maintained substantially the same. Therefore, it is possible to make the distribution of the film thickness of the resin layer deposited on the substrate W uniform and the deposition quality can be improved.

Moreover, in this embodiment, the heater 40 heats the first surface 311 of the shower plate 31. Accordingly, the ultraviolet curable resin layer can be prevented from being deposited on the inner walls of the gas diffusion space 32 and in the through-holes 313. Therefore, the transmittance to an ultraviolet ray is prevented from being lowered due to the deposited resin layer and the transmittance to an ultraviolet ray is maintained stable over a long term. That is, the deposition efficiency can be prevented from lowering over a long term, and the deposition apparatus 100 excellent in the productivity can be provided.

Moreover, since the heater 40 prevents the resin layer from being deposited in the gas diffusion space 32 and on the shower plate 31, particles, which would be produced when the deposited resin layer is peeled off, can also be prevented. Accordingly, the inside of the deposition space 11 can be kept clean and the maintenance can be thus easier. Moreover, the heater 40 can prevent the peeled off resin from sticking to the substrate W during deposition, and the deposition quality can be further improved.

In addition, the heater 40 includes the transparent conductive film 41 configured to cover the entire first surface 311 of the shower plate 31. Accordingly, it is possible to more uniformly heat the surface of the shower plate 31 while maintaining the transmittance of the shower plate 31 to the ultraviolet ray UV. Therefore, the resin layer can be more effectively prevented from being deposited on the inner walls of the gas diffusion space 32 and in the through-holes 313.

In addition, since the heater 40 is configured integrally with the shower plate 31, additional maintenance for the heater 40 is unnecessary. Accordingly, the maintenance for the deposition apparatus 100 can be easier.

Moreover, since the transparent conductive film 41 includes the holes 411 that communicate with the through-holes 313, it is possible to effectively heat the through-holes 313 while keeping the function of supplying the raw material gas in the through-holes 313. Therefore, it is possible to more reliably prevent the through-holes 313 from being clogged with sticking resin.

### OTHER EMBODIMENTS

The configuration of the shower plate 31 is not limited to the above-mentioned configuration.

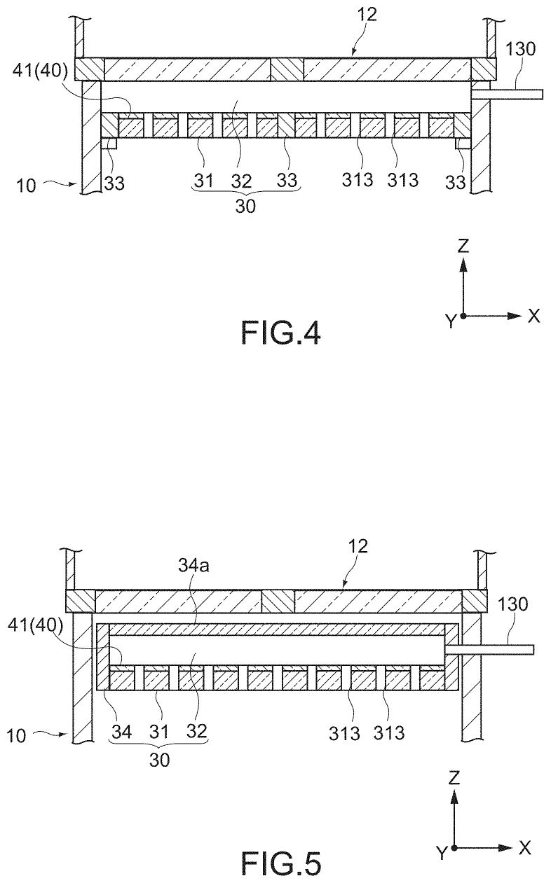

For example, as shown in a main-part cross-sectional view in FIG. 4, the gas supply 30 may include a plurality of shower plates 31, a frame portion 33 that supports the plurality of shower plates 31, and the gas diffusion space 32. Since the shower plate 31 is divided, the size of each shower plate 31 can be reduced and the manufacturing cost of the gas supply 30 can be saved.

Moreover, the gas diffusion space 32 of the gas supply 30 is formed by the shower plate 31 and the top plate 12 of the chamber 10 in the above description, though it is not limited to this configuration. For example, as shown in a main-part cross-sectional view in FIG. 5, the gas supply 30 may include a shower head 34 equipped with the shower plate 31. The shower head 34 is disposed between the stage 15 and the top plate 12 of the deposition space 11 and the gas diffusion space 32 is formed in the inside. Moreover, in the shower head 34, the shower plate 31 and a surface 34a on the side of the top plate 12 are constituted of a material transmissive to an ultraviolet ray. Also with such a configuration, the distribution of the film thickness of the ultraviolet curable resin layer in the substrate W can be made uniform.

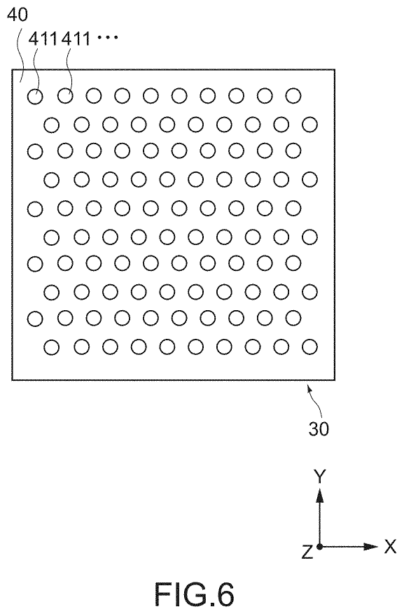

The through-holes 313 of the shower plate 31 and the holes 411 of the transparent conductive film 41 are not limited to the arrangement shown in FIG. 3, and those may be arranged in a zigzag form as shown in FIG. 6, for example. Alternatively, other arrangement may be employed.

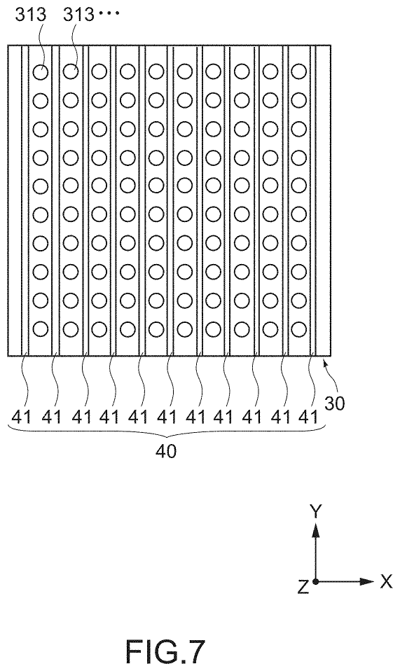

Moreover, the transparent conductive film 41 is not limited to the configuration to cover the entire first surface 311. For example, as shown in a schematic main-part plan view in FIG. 7, the transparent conductive film 41 may be formed in a strip pattern. In this case, the transparent conductive film 41 may be formed between adjacent through-holes 313 of the through-holes 313 as shown in FIG. 7. Moreover, in a case where the transparent conductive film 41 is configured to cover the through-holes 313, the holes 411 may be provided at positions corresponding to the through-holes 313. The transparent conductive film 41 is not limited to the strip pattern, and may be formed in any other pattern.

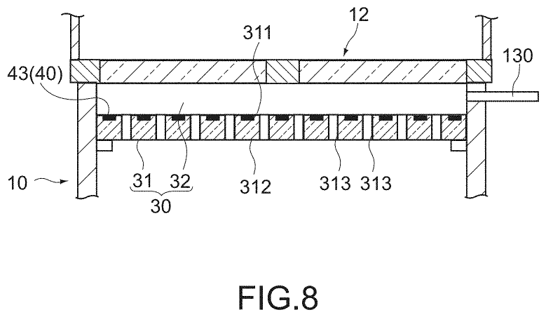

Moreover, the heater 40 is not limited to the configuration including the transparent conductive film 41. For example, as shown in a main-part cross-sectional view in FIG. 8, the heater 40 may include a heater such as a resistance heating line 43 disposed on the side of the first surface 311. The resistance heating line 43 can be a printed wire formed by a printing technique, for example.

In addition, the heater 40 may include a heating source that heats the inner walls of the deposition space 11, the top plate 12, and the like in addition to the transparent conductive film 41.

Hereinabove, the respective embodiments of the present invention have been described. The present invention is not limited to the above-mentioned embodiments and various modifications can be made without departing from the gist of the present invention as a matter of course.

Although the example in which the energy ray is the ultraviolet ray has been shown in the above-mentioned embodiments, the energy ray is not limited thereto. For instance, an electromagnetic wave generated from a power supply at a high frequency, for example, about 13 MHz or 27 MHz may be used. In this case, the emission source can be an oscillator or the like. Alternatively, the energy ray may be an electronic beam and the emission source may be an electronic beam source.

In addition, the deposition apparatus according to each of the above-mentioned embodiments may be used as a part of an in-line or cluster deposition apparatus including a plurality of chambers, for example. The use of such an apparatus makes it easier to fabricate a device having a plurality of layers like a light-emitting device and the like. Moreover, with such an apparatus, cost saving, space saving, and further improvement in the productivity can be achieved.

### REFERENCE SIGNS LIST

10 chamber
11 deposition space
12 top plate
13 aperture
15 stage
20 light source
22 emission source
30 gas supply
31 shower plate
32 gas diffusion space
40 heater
41 transparent conductive film
100 deposition apparatus
311 first surface
312 second surface
313 through-hole
411 hole

1. A deposition apparatus, comprising:
a chamber including a deposition space;
a stage that is disposed in the deposition space and supports a substrate;
a light source that includes an emission source that emits an energy ray and is disposed to face the deposition space;
a gas supply including
a shower plate including
a first surface that faces the light source,
a second surface that faces the stage, and
a plurality of through-holes that penetrates the first surface and the second surface, the shower plate allowing the energy ray to transmit therethrough, and
a gas diffusion space that faces the first surface and diffuses raw material gas including an energy ray-curable resin that cures when the energy ray-curable resin is irradiated with the energy ray, the gas supply supplying the raw material gas into the deposition space from the gas diffusion space; and
a heater that heats the first surface of the shower plate.

2. The deposition apparatus according to claim 1, wherein
the heater includes a transparent conductive film formed on the first surface of the shower plate.

3. The deposition apparatus according to claim 2, wherein
the transparent conductive film includes indium oxide tin (ITO).

4. The deposition apparatus according to claim 2, wherein
the transparent conductive film has a plurality of holes that communicates with the plurality of through-holes.

5. The deposition apparatus according to claim 1, wherein
the shower plate is constituted of quartz glass.

6. The deposition apparatus according to claim 1, wherein
the chamber further includes
an aperture that makes the deposition space opened to the light source, and
a top plate that closes the aperture and allows the energy ray to transmit therethrough, and
the gas diffusion space is configured as a space sandwiched between the top plate and the shower plate.
